(19) United States
(12) Patent Application Publication
(10) Pub. No.: US 2010/0289507 A1
(43) Pub. Date: Nov. 18, 2010

(54) MULTICONTACT TRANSPARENT TACTILE SENSOR BASED ON A METALIZED SURFACE DEPOSITION

(75) Inventors: Pascal Joguet, Sadirac (FR); Guillaume Largillier, Bordeaux (FR); Julien Olivier, Bordeaux (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: Stantum, Bordeaux (FR)

(21) Appl. No.: 12/808,841

(22) PCT Filed: Dec. 19, 2008
(86) PCT No.: PCT/FR2008/001806

§ 371 Date: Jun. 17, 2010

(30) Foreign Application Priority Data
Dec. 19, 2007 (FR) 0760022

(51) Int. Cl. G01R 27/26

(52) U.S. Cl. 324/686

(57) ABSTRACT

A multicontact transparent tactile sensor including two at least partially conducting transparent layers, the layers being spaced apart by an insulating transparent material. At least one of the layers includes a transparent sheet on which is deposited an array of conducting tracks whose width is less than 80 microns.

The present invention concerns a multicontact transparent tactile sensor based on a metalized surface deposition.

The present invention concerns the field of passive-matrix multicontact transparent tactile sensors.

This type of sensor is provided with means for simultaneous acquisition of the position, the pressure, the size, the shape and the movement of a plurality of fingers on its surface in order to control equipment, preferably via a graphical interface.

Said sensors can be used in many devices such as mobile telephones, computers, etc. This list is not limiting on the present invention.

There are known in the art resistive tablet multicontact transparent tactile sensors. These sensors advantageously comprise a transparent semiconductor or insulative layer situated between two transparent conductive layers on which are printed rows or columns corresponding to conductive wires.

Said conductive layers are thus arranged in a matrix of nodes formed by the intersection of rows and columns. The semiconductor layer serves as an open switch when the tactile sensor is not touched and a closed switch when the tactile sensor is touched, which brings the two conductive layers into contact.

Said conductive layers are generally deposited on glass or polyester substrates. They serve as electrodes and each has on one of its surfaces a conductive layer produced in a transparent conductive material, which material may further consist of indium-tin oxide (ITO), conductive polymers, carbon nanotubes or any other transparent conductive material.

There has been proposed in the prior art a solution described in the patent FR 2,866,726 aimed at a device further including a bidimensional multicontact sensor for the acquisition of tactile information.

Said sensor as described in said patent consists of a resistive matrix tablet consisting of two transparent conductive layers on which are printed rows or columns corresponding to conductive wires and an insulative material between said two transparent conductive layers. A prior art transparent conductive layer is advantageously produced in ITO, which is a conductive material and transparent in very thin layers.

An ITO-based solution has a number of drawbacks, including:
a loss of brightness and contrast caused by the optical characteristics of ITO, which entails among other things more powerful backlighting of the display screen and thus a higher consumption of the latter,
distortion of the visible spectrum caused by the coloration of the material used,
too high an electrical resistance of the material, which complicates the processing circuit,
the rarity and rising cost of the material, despite increasing consumption, which makes procurement more and more difficult.

Among other alternatives to ITO, conductive polymers are neither sufficiently conductive nor sufficiently transparent and the carbon nanotube technology is at present not sufficiently mastered.

The object of the present invention is to remedy this drawback by proposing a multicontact transparent tactile sensor further including at least one transparent layer consisting of conductive tracks consisting of deposited metal.

This metal layer has better conductivity and makes it possible to produce the tactile sensor at lower cost avoiding the problems of ITO procurement. Moreover, greater transparency of the sensor is possible through metal deposits of the order of one micrometer or even one nanometer.

To this end, the present invention proposes a multicontact transparent tactile sensor including two at least partially conductive transparent layers spaced by an insulative transparent material, characterized in that at least one of said layers consists of a transparent film on which is deposited an array of conductive tracks the width of which is less than 80 microns.

Preferably, no transparent film of a transparent layer includes deposited ITO, conductive polymers, carbon nanotubes or any other transparent conductive material.

Each of the two layers advantageously consists of a transparent film on which is deposited an array of conductive tracks electrically insulated from each other, the width of which is less than 80 microns.

The arrays of conductive tracks preferably consist of an opaque conductive material.

In one particular embodiment of the present invention, the material used for the conductive tracks is copper, silver, gold, aluminum or alloys of conductive metals.

The arrays of conductive tracks of the two layers are preferably perpendicular to each other.

In one particular embodiment of the present invention, the other transparent layer includes a transparent conductive surface coating.

This other transparent layer preferably includes a conductive ITO surface coating.

In another particular embodiment of the present invention, this other transparent layer includes a capacitive sensor.

In another particular embodiment of the present invention, this other transparent layer includes a sprayed capacitive sensor.

In a first embodiment of the present invention, the upper layer consists of a polyester film with a thickness of 125 microns.

In a second embodiment of the present invention, the upper layer consists of a glass film with a thickness of 20 microns.

In one particular embodiment of the present invention, the lower layer consists of a glass plate with a dimension between 0.1 and 3 millimeters inclusive.

In another particular embodiment of the present invention, the lower layer consists of a flexible glass film.

The interlayer spacing is advantageously between 12 and 40 microns inclusive.

The conductive tracks of the same array of conductive tracks are advantageously parallel and equally spaced.

The array of conductive tracks preferably consists of deposited thin metal wires the width of which is less than 80 microns.

The present invention will be better understood on reading the detailed description of one nonlimiting embodiment of the present invention, accompanied by appended figures respectively showing:

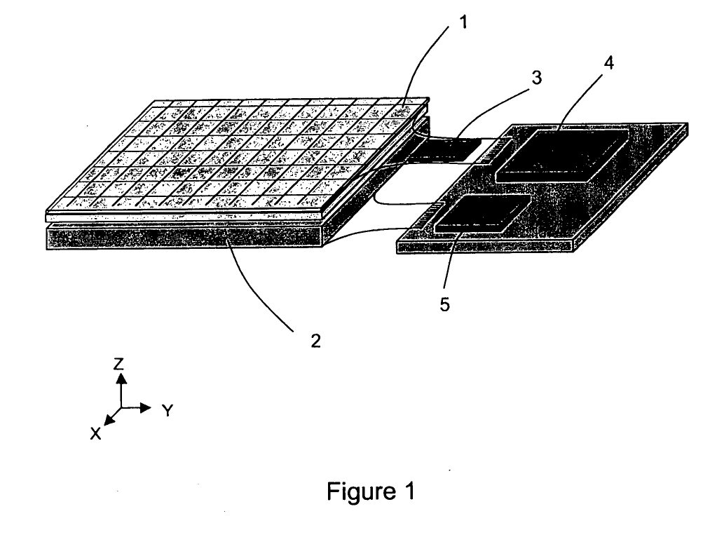

FIG. 1, a view in three dimensions of the structure of an electronic device comprising a multicontact transparent tactile sensor of the present invention,

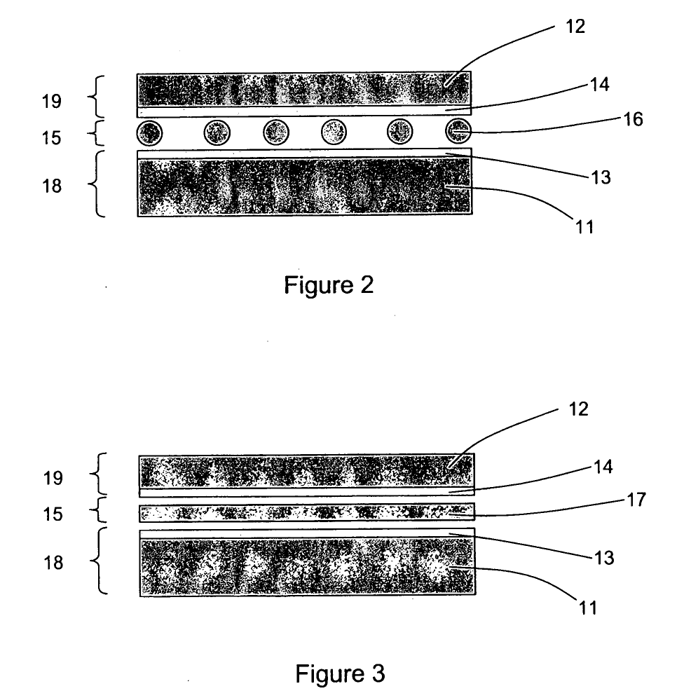

FIG. 2, a view in section of a prior art multicontact tactile sensor with spacing points,

FIG. 3, a view in section of a prior art multicontact tactile sensor comprising a transparent resistive layer,

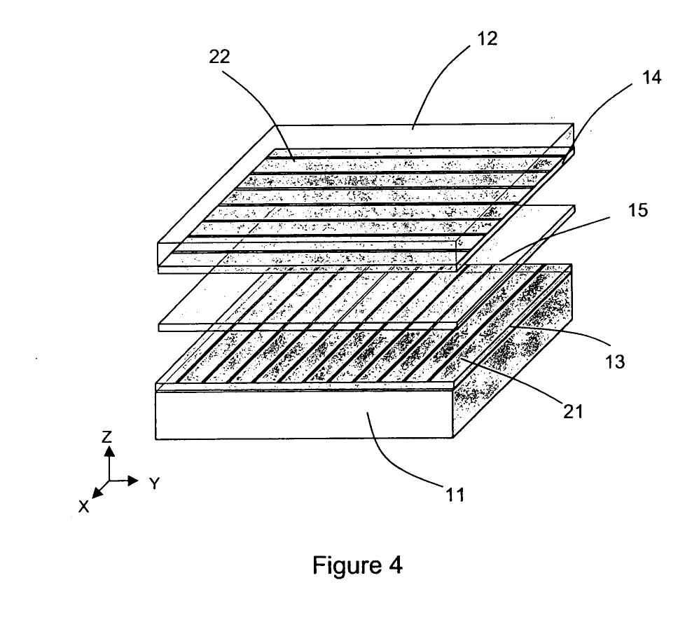

FIG. 4, a view in three dimensions of a prior art multicontact tactile sensor,

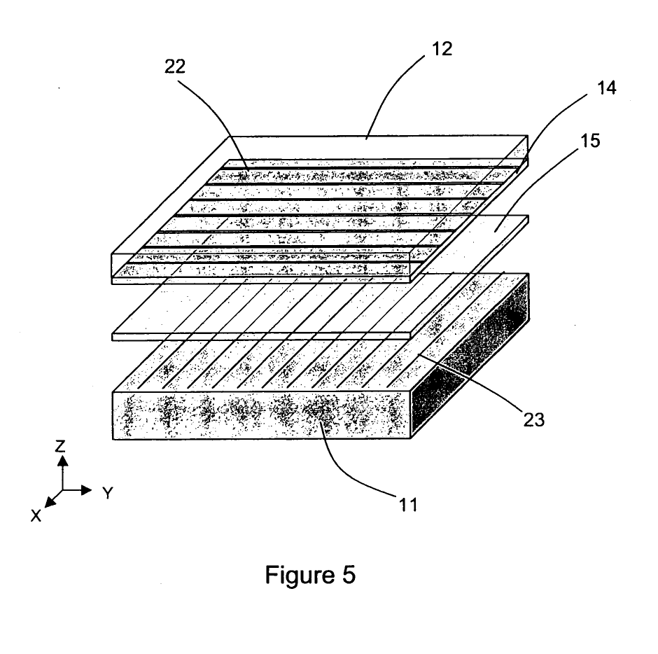

FIG. 5, a view in three dimensions of a multicontact tactile sensor of a first embodiment of the present invention,

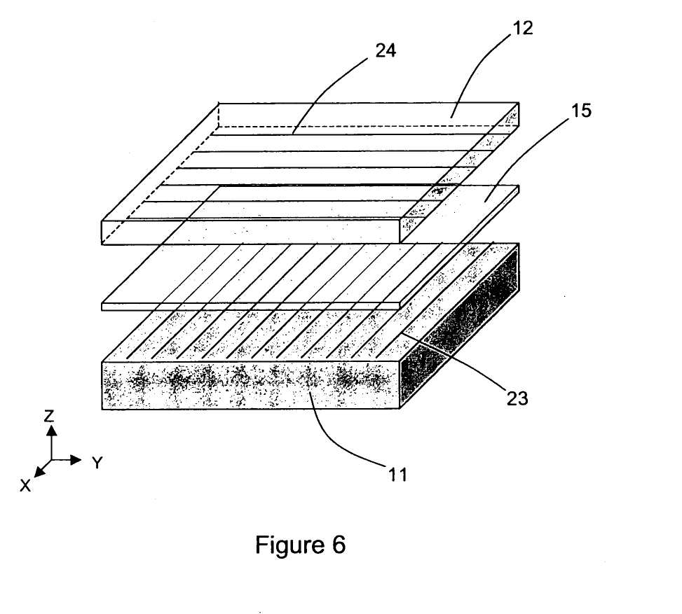

FIG. 6, a view in three dimensions of a multicontact tactile sensor of a second embodiment of the present invention,

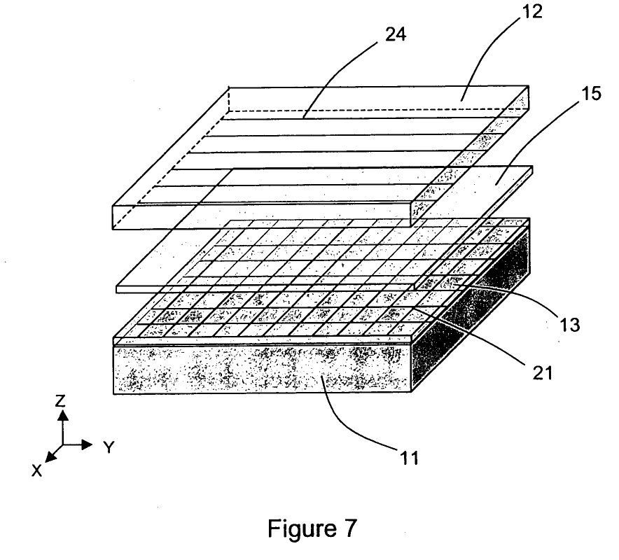

FIG. 7, a view in three dimensions of a multicontact tactile sensor of a third embodiment of the present invention, and

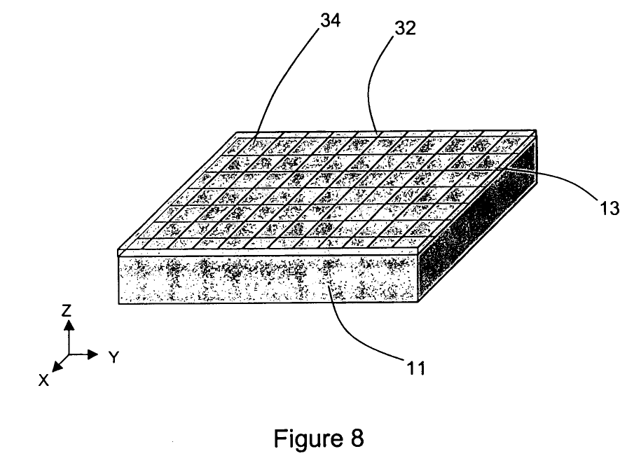

FIG. 8, a view in three dimensions of the capacitive tablet of the tactile sensor of the third embodiment of the present invention.

A multicontact transparent tactile sensor of the present invention is intended to be integrated into a multicontact tactile display screen.

FIG. 1 represents a view of a tactile electronic device comprising:
a matrix tactile sensor 1,
a display screen 2,
a capture interface 3,
a main processor 4, and
a graphics processor 5.

The first fundamental element of said tactile device is the matrix tactile sensor 1, necessary for acquisition—multicontact manipulation—with the aid of a capture interface 3. Said tactile sensor 1 is of matrix type. This capture interface 3 includes the acquisition and analysis circuits.

Said sensor may where appropriate be divided into a plurality of parts in order to accelerate capture, each part being scanned simultaneously.

Data from the capture interface 3 is transmitted after filtering to the main processor 4. The latter executes the local program for associating the data from the sensor with graphic objects that are displayed on the display screen 2 in order to be manipulated.

The main processor 4 also sends the graphical interface 5 the data to be displayed on the screen 2. This graphical interface can furthermore be driven by a graphics processor.

FIGS. 2 to 4 represent views of an assembly of layers intended to produce a prior art multicontact transparent sensor. That sensor has a matrix resistive tablet of known type.

A matrix resistive tactile tablet has two superposed faces on which ITO tracks are organized.

Said sensor 1 further comprises:
a glass substrate 11,
a polyester film 12,
two ITO conductive surfaces 13 and 14,
an insulative layer 15.

Said sensor 1 is a resistive tactile sensor. To this end, the two conductive surfaces 13 and 14 serve as electrodes.

Said two ITO conductive surfaces (13, 14) can equally be produced in another transparent conductive material, such as a conductive polymer, although this is not limiting on the present invention.

In the case of two ITO conductive surfaces, each of the two surfaces comprises ITO tracks organized over the whole of said surface.

The ITO conductive surface 14 of the upper layer 19 comprises tracks 22 disposed in rows along the axis X as shown in FIG. 4. The ITO conductive surface 13 of the lower layer 18 comprises tracks 21 disposed in columns along the axis Y as shown in FIG. 4. The combination of these two surfaces 13 and 14 thus forms a matrix of ITO tracks. The converse row/column is equally possible.

The conductive tracks of the same array of conductive tracks are advantageously parallel and equally spaced.

The insulative layer 15 serves as a switch: it is open when no finger—or other object intended to touch the sensor—comes into contact with said sensor 1 and it is closed in the case of a contact.

Said insulative layer 15 may consist of spacing points 16 as shown in FIG. 2.

Said spacing points 16 are advantageously replaced by a layer of transparent resistive material 17, for example a conductive polymer, the resistance of which varies as it is crushed, decreasing if a sufficient bearing force is exerted.

To find out if a row has been brought into contact with a column (which defines a point of contact on the tablet) it suffices to measure the voltage at the terminals of the switch.

The glass substrate 11 is the support member of the sensor 1 on which the other elements 12 to 15 are placed. Its transparency enables sufficient clarity for viewing the graphic objects on the display screen 2 through the sensor 1.

The polyester film 12 enables the sensor to resist scratches caused by a stylus, for example.

In this embodiment of the present invention, the two conductive surfaces 13 and 14 are insulated from each other by the insulative layer 15. The intersection of a row and a column forms a contact point. When a finger is placed on the tablet, for example, one or more columns located on the upper layer 19 are brought into contact with one or more rows located on the lower layer 18, thus creating one or more points of contact.

In this prior art embodiment, the clearness of the resistive tactile sensor is reduced by the ITO conductive surfaces. Moreover, use of an embodiment of this kind is proving more and more complicated because of the increasing rarity of ITO. The following embodiments of the present invention aim to alleviate these drawbacks.

FIG. 5 represents a view of an assembly of layers intended to implement a first embodiment of a multicontact transparent tactile sensor of the present invention.

The sensor 1 of this embodiment of the present invention has only one ITO conductive surface 14. The ITO conductive surface 13 has been replaced by a deposited linear layer of thin wires 23.

The ITO conductive surface 14 comprises tracks 22 arranged in rows while the thin wires 23 are arranged in columns. The combination of these tracks 22 and 23 thus forms a conductive track matrix. The converse row/column is equally possible.

Said thin wires 23 have a size less than 80 microns and preferably a size less than 20 microns, in order not to mask the display screen.

In the present embodiment, the thin wires 23 are deposited on the glass plate 11. Said glass plate 11 has a thickness between 0.1 and 3 millimeters inclusive.

In another embodiment, the glass plate may be replaced by a flexible glass film.

The ITO conductive surface 14 can equally consist of any other transparent conductive surface coating.

Said upper ITO conductive surface 14 is deposited under the polyester film 12. Said polyester film has a thickness of 125 microns.

In another embodiment, said polyester film is replaced by a taut glass film with a thickness of 100 microns.

The interlayer spacing between the glass plate 11 and the polyester film 12 is between 12 and 40 microns inclusive.

In the present embodiment of the present invention, the sensor 1 has no more than one deposited ITO conductive surface likely to mask the tactile screen. Consequently, the transparency of the sensor is improved over the prior art, which also reduces the consumption of said display screen.

FIG. 6 represents a view of an assembly of layers intended to implement a multicontact transparent tactile sensor of a second embodiment of the present invention.

The sensor 1 of this embodiment of the present invention no longer includes an ITO conductive surface but includes two deposited linear layers of thin wires 23 and 24.

The thin wires 24 of the upper layer 19 are disposed in rows whereas the thin wires 23 of the lower layer 18 are disposed in columns. The combination of these thin wires 23 and 24 thus forms a matrix of conductive tracks. The converse row/column is equally possible.

Said thin wires 23 and 24 have a dimension of less than 80 microns and preferably a dimension of less than 20 microns.

In the present embodiment, the sensor 1 no longer includes a deposited ITO conductive surface. Consequently, the sensor has improved transparency compared to the previous embodiment, which makes it possible to limit the consumption of the display screen by limiting its backlighting power.

FIGS. 7 and 8 represent views of an assembly of layers intended to implement a multicontact transparent tactile sensor of a third embodiment of the present invention. This embodiment of the present invention aims to produce a capacitive/resistive type tablet.

The sensor 1 of this embodiment of the present invention includes an conductive ITO surface 13 comprising an array of conductive tracks 21 on the lower layer 18 and an array of thin wires 22 on the upper layer 19.

The ITO conductive surface 13 on the lower layer 18 comprises tracks 21 disposed in rows whereas the upper layer 19 comprises tracks 24 disposed in columns. The combination of these conductive tracks 21 and 24 thus forms a matrix of conductive tracks. The converse row/column is equally possible.

The ITO conducting surface 13 of the lower layer 18 has in addition to the arrangement of conductive tracks in rows a capacitive sensor (32, 34), as shown in FIG. 8.

Said capacitive sensor (32, 34) is advantageously a sprayed capacitive sensor. It then makes it possible to detect when a finger approaches the sensor 1 but does not necessarily touch it. A capacitive sensor so constructed makes it possible to replace the polyester film 12 with a reinforced glass plate, which provides the tactile screen with optimum strength, which is advantageous.

Counterbalancing reduced transparency compared to the previous embodiment, this embodiment makes it possible to produce capacitive/resistive coupling, which makes it possible to obtain the advantages of each of the two types of measurement without being constrained by their drawbacks.

The capacitive sensor restricts the contact to the fingers or other objects specific to the capacitive sensors at the same time as offering better contact sensitivity. The resistive sensor has a lower sensitivity but is sensitive to any type of contact object.

The present embodiment makes it possible to obtain the sensitivity of a capacitive sensor combined with the diversity of contact objects of a resistive sensor.

A multicontact transparent tactile sensor of the present invention makes it possible to produce a multicontact tactile screen. Said screen has very good properties of clarity and brightness, which makes it possible for it to have reduced electrical consumption because of the reduced necessity to provide backlighting.

The tactile properties of said screen are also improved in that the thin wires disposed in accordance with the present invention have an extremely low resistance.

Finally, the present invention makes it possible to avoid using the material ITO, the rarity and increasing consumption of which oblige the person skilled in the art to seek alternative solutions.

1-15. (canceled)

16. A multicontact transparent tactile sensor comprising:
two at least partially conductive transparent layers spaced by an insulative transparent material, wherein at least one of the layers consists of a transparent film on which is deposited an array of conductive tracks having a width less than 80 microns.

17. A tactile sensor according to claim 16, wherein each of the two layers consists of a transparent film on which is deposited an array of conductive tracks electrically insulated from each other, the width of which is less than 80 microns.

18. A tactile sensor according to claim 17, wherein the array of conductive tracks consists of an opaque conductive material.

19. A tactile sensor according to claim 17, wherein the array of conductive tracks of the two layers are perpendicular to each other.

20. A tactile sensor according to claim 16, wherein the other transparent layer includes a transparent conductive surface coating.

21. A tactile sensor according to claim 20, wherein the other transparent layer includes a conductive ITO surface coating.

22. A tactile sensor according to claim 20, wherein the other transparent layer includes a capacitive sensor.

23. A tactile sensor according to claim 22, wherein the other transparent layer includes a sprayed capacitive sensor.

24. A tactile sensor according to claim 16, wherein the upper layer consists of a polyester film with a thickness of 125 microns.

25. A tactile sensor according to claim 16, wherein the upper layer consists of a glass film with a thickness of 20 microns.

26. A tactile sensor according to claim 16, wherein the lower layer consists of a glass plate with a dimension between 0.1 and 3 millimeters inclusive.

27. A tactile sensor according to claim 16, wherein the lower layer consists of a flexible glass film.

28. A tactile sensor according to claim 16, wherein the interlayer spacing is between 12 and 40 microns inclusive.

29. A tactile sensor according to claim 16, wherein the conductive tracks of the same array of conductive tracks are parallel and equally spaced.

30. A tactile sensor according to claim 16, wherein the array of conductive tracks consists of deposited thin metal wires the width of which is less than 80 microns.
